(19) United States
(12) Patent Application Publication
(10) Pub. No.: US 2015/0060014 A1
(43) Pub. Date: Mar. 5, 2015

(54) SERVER RACK COOLING SYSTEM

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: XIAO-FENG MA, Shenzhen (CN); LEI LIU, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/243,444

(22) Filed: Apr. 2, 2014

(30) Foreign Application Priority Data
Aug. 28, 2013 (CN) 201310379077X

(51) Int. Cl. H05K 7/20

(52) U.S. Cl. CPC H05K 7/20736
USPC 165/80.2; 165/122

(57) ABSTRACT

A server rack includes a plurality of servers received therein. The server rack includes a delivery mechanism, a plurality of main fan groups and a backup fan group for cooling the servers. Each main fan group and the backup fan group both include one or more cooling fans. The delivery mechanism carries the backup fan group and to drive the backup fan group to move within the server rack. When a main fan group is malfunctioned, the backup fan group is moved to a location corresponding to a location of the malfunctioned main fan group to replace the malfunctioned group to cool one or more corresponding servers.

### FIELD

Embodiments of the present disclosure relate to cooling technologies, and particularly to, a cooling system used in a server rack having a plurality of servers.

### BACKGROUND

Server racks are widely used to receive a plurality of servers. When the servers of the server racks are working, a great amount of heat may be produced in the server racks. In a typically cooling method for a server rack, a single fan group including one or more cooling fans is shared by one or more servers to cool the servers.

However, when the single fan group does not work due to malfunctions, the servers cooled by this group of fans may work unstably due to a high temperature. Therefore, there is room for improvement in the art.

### BRIEF DESCRIPTION OF THE DRAWINGS

FIG. 1 is a schematic rear view of one embodiment of a server rack.

FIG. 2 is a schematic top view of one embodiment of the server rack of FIG. 1.

FIG. 3 is a schematic block diagram of a cooling system used for cooling servers of the server rack of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

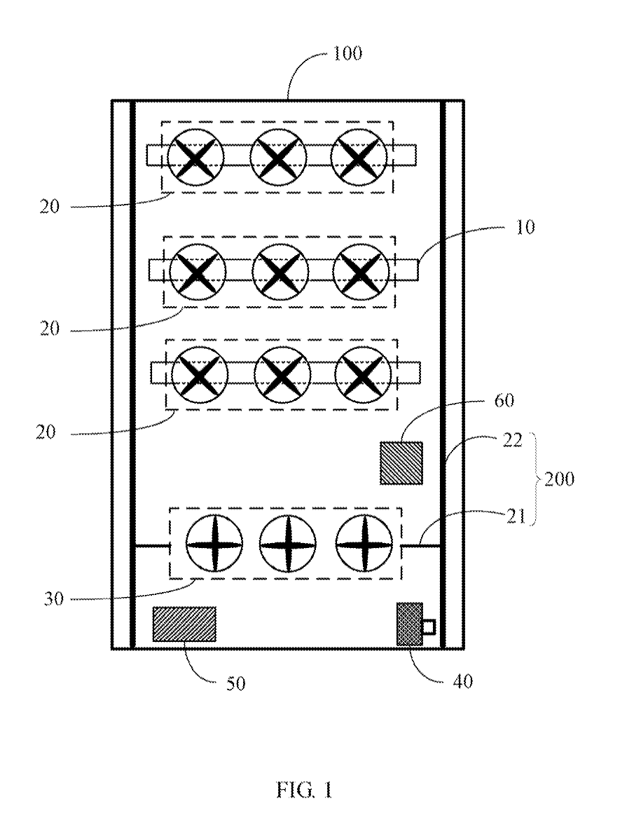

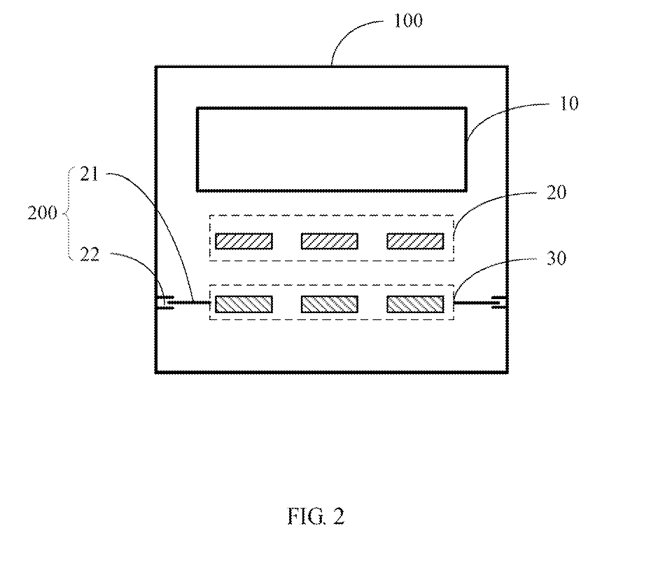

FIG. 1 and FIG. 2 show a server rack 100 configured to receive a plurality of servers 10. The server rack 100 includes a plurality of main fan groups 20 for cooling the servers 10 of the server rack 100. Each of the main fan groups 20 includes one or more cooling fans. In this embodiment, each main fan group 20 is arranged corresponding to one or more servers 10 to cool the one or more servers 10.

The server rack 100 further includes a backup fan group 30. When a main fan group 20 does not work, the backup fan group 30 moves to a location corresponding to the main fan group 20 to replace the main fan group 20 to cool one or more corresponding servers 20. The backup fan group 30 includes one or more cooling fans.

In this embodiment, the server rack 100 further includes a delivery mechanism 200 to carry the backup fan group 30. The delivery mechanism 200 can drive the backup fan group to move within the server rack 100. FIG. 2 shows that the servers 10, the main fan groups 20, and the backup fan group 30 are respectively located at different planes. A plane in which the main fan groups 20 resides spaces a predetermined distance from a plane in which the backup fan group 30 resides, so that the backup fan group 30 cannot be blocked by the main fan groups 20 during moving within the server rack 100.

In this embodiment, the delivery mechanism 200 includes a sliding structure 22 and a connecting member 21. The sliding structure 22 defines a sliding track. The connecting member 21 connects the backup fan group to the sliding structure 22. A motor 40 is located in the server rack 100 to drive the backup fan group 30 to slide along the sliding track. The motor 40 can be a servo motor.

In one embodiment, the sliding structure 22 includes two sliding grooves respectively located at two opposite inner sidewalls of the server rack 100. Thus, the backup fan group 30 can slide along the sliding grooves under the drive of the motor 40. In another embodiment, the sliding structure 22 includes two sliding rails respectively located at the two opposite sides of the server rack 100. Thus, the backup fan group 30 can slide on the sliding rails under the drive of the motor 40. In this embodiment, the sliding structure 22 and the backup fan group 30 are located in a same plane making the backup fan group stably move in the plane.

The server rack 100 further includes a motor controller 50 and fan controller 60. The motor controller 50 is configured to control the motor 40. The fan controller 60 is configured to control the main fan groups 20 and the backup fan group 30. For example, a rotation speed of the cooling fans of the main fan groups 20 and the backup fan group 30 is controlled by the fan controller 60 according to a real-time temperature of corresponding servers 10. In this embodiment, the main fan groups 20, the backup fan group 30, the motor 40, the motor controller 50, and the fan controller 60 corporately form a cooling system of the server rack 100.

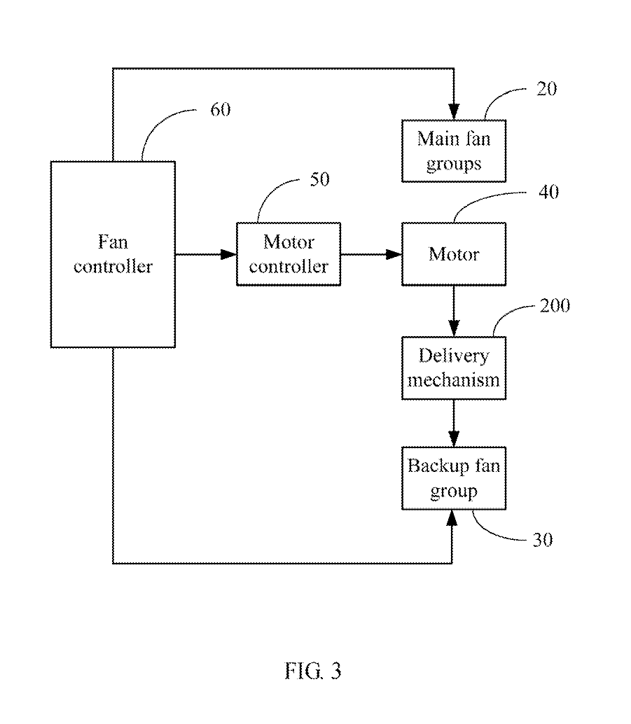

FIG. 3 shows a schematic block diagram of the cooling system. The fan controller 60 is electrically connected to the motor controller 50, the backup fan group 30, and each of the main fan groups 20. The fan controller 60 monitors a real-time working state of each of the main fan groups 20 to detect whether or not the main fan groups 20 are malfunctioned. When a malfunctioned main fan group 20 is monitored by the fan controller 60, the fan controller 60 sends a trigger signal to the motor controller 50. In this embodiment, the trigger signal includes location data indicating a location where the malfunctioned main fan group 2 is located. The fan controller 60 can be a baseboard management controller (BMC) located in the server rack. The BMC (not shown) is used to monitor working states of the plurality of servers 10. In other embodiments, the fan controller 60 can be a control device (e.g., a processor) of one of the servers 10.

When the motor controller 50 receives the trigger signal from the fan controller 60, the motor controller 50 controls the motor 40 to drive the backup fan group 30 to move to a location corresponding to the location of the malfunctioned main fan group 20 via the delivery mechanism 200. Thus, the backup fan group 30 replaces the malfunctioned main fan group to cool one or more servers 10, which are previously cooled by the malfunctioned main fan group 20.

In this embodiment, the motor controller 50 first calculates a distance that the backup fan group 30 needs to be moved according to the trigger signal, and then sends a control command according to the calculated distance to the motor 40 to drive the backup fan group 30 to move the calculated distance via the delivery mechanism 200. In one embodiment, a distance between the location of the backup fan group 30 and the location of each of the main fan groups 20 is prestored in the motor controller 50. Thus, the motor controller 50 can directly obtain the distance that the backup fan group 30 needs to be moved according to the location of the malfunctioned main fan group 20.

When the backup fan group 30 is moved to the location corresponding to the malfunctioned main fan group 20, the fan controller 60 controls the backup fan group 30 to start working and outputs a warning message to warn a user that one of the main fan groups 20 is malfunctioned. In one embodiment, the warning message may be an audible output from a buzzer of the fan controller. In other embodiments, the warning message can be a text message sent to a device (e.g., a smart phone or a personal computer) of the user via one of the servers 10.

When the fan controller 60 detects that the malfunction of the malfunctioned main fan group 20 is eliminated (e.g., the malfunctioned main fan group 20 starts to work again), the fan controller 60 controls the backup fan group 30 to stop working Then, the fan controller 60 outputs a comeback signal to the motor controller 50. The motor controller 50 controls the motor 40 to drive the backup fan group 30 to return to an original location via the delivery mechanism 200. The original location can be pre-stored in the motor controller 50.

It will be understood that the backup fan group 30 can be manually moved via the delivery mechanism 200. That is, some elements of the cooling system such as the motor 40, the motor controller 50, and the fan controller 60 can be omitted in some embodiments.

As described above, when one or the main fan groups 20 is malfunctioned, the backup fan group 30 can be used to replace the malfunctioned main fan group 20 to cool corresponding servers 20. Thus, the stability of the servers is improved.

Although certain embodiments of the present disclosure have been specifically described, the present disclosure is not to be construed as being limited thereto. Various changes or modifications may be made to the present disclosure without departing from the scope and spirit of the present disclosure.

What is claimed is:

1. A server rack configured to receive a plurality of servers, comprising:
a plurality of main fan groups and a backup fan group for cooling the servers, wherein each main fan group and the backup fan group both comprise one or more cooling fans; and
a delivery mechanism configured to carry the backup fan group and to drive the backup fan group to move within the server rack, wherein when a main fan group is malfunctioned, the backup fan group is moved to a location corresponding to a location of the malfunctioned main fan group to replace the malfunctioned group to cool one or more corresponding servers.

2. The server rack according to claim 1, wherein a plane in which the main fan groups resides spaces a predetermined distance from a plane in which the backup fan group resides.

3. The server rack according to claim 1, wherein the delivery mechanism comprises a sliding structure and a connecting member, the sliding structure defines a sliding track, the connecting member connects the backup fan group to the sliding structure to allow the backup fan group capable of sliding along the sliding track.

4. The server rack according to claim 3, wherein the sliding structure comprises two sliding grooves respectively located at two opposite inner sidewalls of the server rack, and the backup fan group is capable of sliding along the sliding grooves.

5. The server rack according to claim 3, wherein the sliding structure comprises two sliding rails respectively located at two opposite sides of the server rack, and the backup fan group is capable of sliding on the sliding rails.

6. The server rack according to claim 2, further comprising a fan controller, a motor, and a motor controller, wherein:
the motor drives the backup fan group to move along the sliding track defined by the sliding structure;
the fan controller is electrically connected to the motor controller, the backup fan group, and each of the main fan groups, the fan controller monitors a real-time working state of each of the main fan groups and sends a trigger signal to the motor controller when a malfunctioned main fan group is monitored; and
the motor controller is electrically connected to the motor, and controls the motor to drive the backup fan group to move to the location corresponding to the location of the malfunctioned main fan group via the delivery mechanism according to the trigger signal.

7. The server rack according to claim 6, wherein the trigger signal comprises location data indicating the location where the malfunctioned main fan group is located; the motor controller first calculates a distance that the backup fan group needs to be moved according to the trigger signal, and then sends a control command according to the calculated distance to the motor to drive the backup fan group to move the calculated distance via the delivery mechanism.

8. The server rack according to claim 7, wherein the a distance between the location of the backup fan group and a location of each of the main fan groups is prestored in the motor controller, and the motor controller obtains the distance that the backup fan group needs to be moved according to the location of the malfunctioned main fan group.

9. The server rack according to claim 6, wherein when the backup fan group is moved to the location corresponding to the location of the malfunctioned main fan group, the fan controller controls the backup fan group to start working and outputs a warning message to warn a user that one of the main fan groups has malfunctioned.

10. The server rack according to claim 6, wherein when the fan controller detects that the malfunction of the malfunctioned main fan group is eliminated, the fan controller controls the backup fan group to stop working and outputs a comeback signal to the motor controller, and the motor controller controls the motor to drive the backup fan group to return to an original location via the delivery mechanism.

11. A cooling system configured to cool a plurality of servers of a server rack having a delivery mechanism, comprising:
a plurality of main fan groups and a backup fan group for cooling the servers, each main fan group and the backup fan group both comprising one or more cooling fans, and the backup fan group being carried by the delivery mechanism to move within the server rack;
wherein when a main fan group is malfunctioned, the backup fan group is moved to a location corresponding to a location of the malfunctioned main fan group to replace the malfunctioned group to cool one or more corresponding servers.

12. The cooling system according to claim 11, wherein a plane in which the main fan groups resides spaces a predetermined distance from a plane in which the backup fan group resides.

13. The cooling system according to claim 11, wherein the delivery mechanism comprises a sliding structure and a connecting member, the sliding structure defines a sliding track, the connecting member connects the backup fan group to the sliding structure to allow the backup fan group capable of sliding along the sliding track.

14. The cooling system according to claim 13, wherein the sliding structure comprises two sliding grooves respectively located at two opposite inner sidewalls of the server rack, and the backup fan group is capable of sliding along the sliding grooves.

15. The cooling system according to claim 13, wherein the sliding structure comprises at least two sliding rails respectively located at two opposite sides of the server rack, and the backup fan group is capable of sliding on the sliding rails.

16. The cooling system according to claim 12, further comprising a fan controller, a motor, and a motor controller, wherein:
the motor drives the backup fan group to move along the sliding track defined by the sliding structure;
the fan controller is electrically connected to the motor controller, the backup fan group, and each of the main fan groups, the fan controller monitors a real-time working state of each of the main fan groups and sends a trigger signal to the motor controller when a malfunctioned main fan group is monitored; and
the motor controller is electrically connected to the motor, and controls the motor to drive the backup fan group to move to the location corresponding to the location of the malfunctioned main fan group via the delivery mechanism according to the trigger signal.

17. The cooling system according to claim 16, wherein the trigger signal comprises location data indicating the location where the malfunctioned main fan group is located; the motor controller first calculates a distance that the backup fan group needs to be moved according to the trigger signal, and then sends a control command according to the calculated distance to the motor to drive the backup fan group to move the calculated distance via the delivery mechanism.

18. The cooling system according to claim 17, wherein the a distance between the location of the backup fan group and a location of each of the main fan groups is prestored in the motor controller, and the motor controller obtains the distance that the backup fan group needs to be moved according to the location of the malfunctioned main fan group.

19. The cooling system according to claim 16, wherein when the backup fan group is moved to the location corresponding to the location of the malfunctioned main fan group, the fan controller controls the backup fan group to start working and outputs a warning message to warn a user that one of the main fan groups is malfunctioned.

20. The cooling system according to claim 16, wherein when the fan controller detects that the malfunction of the malfunctioned main fan group is eliminated, the fan controller controls the backup fan group to stop working and outputs a comeback signal to the motor controller, and the motor controller controls the motor to drive the backup fan group to return to an original location via the delivery mechanism.
